(19) United States
(12) Patent Application Publication
(10) Pub. No.: US 2012/0295398 A1
(43) Pub. Date: Nov. 22, 2012

(54) ION IMPLANT MODIFICATION OF RESISTIVE RANDOM ACCESS MEMORY DEVICES

(75) Inventors: Peter Kurunczi, Cambridge, MA (US); John Hautala, Beverly, MA (US)

(73) Assignee: VARIAN SEMICONDUCTOR EQUIPMENT ASSOCIATES, INC., Gloucester, MA (US)

(21) Appl. No.: 13/468,154

(22) Filed: May 10, 2012

Related U.S. Application Data
(60) Provisional application No. 61/486,516, filed on May 16, 2011.

(51) Int. Cl. H01L 47/00

(52) U.S. Cl. 438/104; 257/E47.005

(57) ABSTRACT

An improved method of fabricating a resistive memory device is disclosed. A resistive memory includes a bottom electrode, a top electrode and a resistive material layer interposed therebetween. Interfaces are formed between the resistive material layer and the respective top and bottom electrodes. Ions are implanted in the device to change the characteristics of one or both of these interfaces, thereby improving the performance of the memory device. These ions may be implanted after the three layers are fabricated, during the fabrication of these layers, or at both times.

This application claims priority of U.S. Provisional Patent Application Ser. No. 61/486,516, filed May 16, 2011, the disclosure of which is incorporated herein by reference in its entirety.

### FIELD

This invention relates to improvements in the operation and yield of resistive random access memory, and more particularly, to modification of the electrode/resistive material interfaces.

### BACKGROUND

Resistive memory devices, or more generically, memristors, have attracting significant attention since being widely publicized in 2008. Fundamentally, a resistive memory device is comprised of a stack of materials in a confined cell. FIG. 1 shows a representative resistive memory cell device 10. The dimensions of the device 10 may be in the range of 10-100 nm in diameter and 30-200 nm in height. The device 10 typically comprises three components, surrounded by a dielectric 60. There is a bottom electrode 20, which may be between 10-50 nm in thickness. This bottom electrode 20 is typically a metal, such as, but not limited to nickel, hafnium, titanium, titanium nitride, tantalum, tantalum nitride, tungsten, copper, platinum, and silver. A resistive material layer 30 is fabricated on the bottom electrode 20. In some embodiments, this resistive material layer 30 is deposited using chemical vapor deposition (CVD) or another deposition process, although other methods of forming the resistive material layer 30 may also be used. Above the resistive material layer 30 is a top electrode 40, which is typically a metal, such as but not limited to, titanium, titanium nitride, tungsten, nickel, hafnium, tantalum, tantalum nitride, copper, platinum or silver. Similar to the bottom electrode 20, the top electrode 40 may be between 10-50 nm in thickness.

The resistive material layer 30 is responsible for switching and maintaining at least two different states. In the case of resistive RAM, also referred to ReRAM, the resistive material layer 30 is capable of achieving two different states, where the resistance of the resistive material layer 30 is different between these two states. For example, a dielectric material may be used as the resistive material layer 30. This dielectric material typically has a high resistance. However, upon application of sufficient voltage across the bottom electrode 20 and top electrode 40, a conductive path is formed through the dielectric material as a result of dielectric breakdown caused by the resulting electric field produced by the applied voltage. This conductive path may be referred to as a filament, and may occur along a region with a high density of conducting defects in the resistive material layer 30, although other mechanisms may also cause this filament to form. For example, a conductive path may form along a path of charged oxygen vacancies.

Once created, this filament may be destroyed by the application of an appropriate current, which thermally anneals the damage caused by the initial application of the high electric field. Once repaired, the dielectric material may again be forced to produce a conductive path through a second application of voltage across the bottom electrode 20 and top electrode 40. Thus, this dielectric material has two distinct states, a low resistance state, where a filament provides a conduction path, and a high resistance state, where the inherent resistance of the dielectric material is observed.

In the case of ReRAM, the resistive material layer 30 is typically a transition metal oxide, such as but not limited to hafnium oxide (HfOₓ), hafnium silicon oxide (HfSiOₓ), copper oxide (CuOₓ), nickel oxide (NiOₓ), titanium oxide (TiOₓ), titanium oxynitride (TiOₓN_{y}), tantalum oxide (TaOₓ), zirconium oxide (ZrOₓ), tungsten oxide (WOₓ) or aluminum oxide (AlOₓ).

A resistive material layer 30 may also be used to create a conducting bridge RAM, or CBRAM. In this configuration, metal ions dissolved within the resistive material flow through the resistive material to form a conductive path between the top electrode 40 and the bottom electrode 20. This conductive path may be referred to as a nanowire. In some embodiments, a first of the bottom electrode 20 or top electrode 40 is electrochemically active, such as silver or copper, while a second of the bottom electrode 20 and top electrode 40 is more inert. Upon the application of negative bias to the second electrode, metal ions in the resistive material flow to form a nanowire between the bottom electrode 20 and top electrode 40, which lowers the resistance through the resistive material layer 30. The first electrode, which is electrochemically active, can also liberate conductive metal ions into the resistive material when the negative bias is applied to the second electrode. When a positive voltage is applied to the second electrode, the metal ions flow away from the nanowire, and back into the first electrode, thereby increasing the resistance of the resistive material. Therefore, like ReRAM, two distinct states are created where a conductive path is created through the resistive material. In the case of CBRAM, the resistive material layer 30 may be, but is not limited to, germanium sulfide (GeSₓ), or germanium selenide (GeSeₓ). In some embodiments, these materials are doped with a metal, such as copper or silver.

A resistive material layer 30 may also be used to create a phase change RAM, or PCRAM. In this configuration, the resistive material is a chalcogenide glass. With the application of appropriate heat and subsequent cooling, this material can be repeatedly transformed between a high resistance amorphous state and a low resistance crystalline state. In the case of PCRAM, the resistive material layer 30 may be an alloy of germanium, antimony and tellurium (Ge—Sb—Te, or GST) or an alloy of germanium and tellurium (Ge—Te).

These three components, the bottom electrode 20, resistive material layer 30 and top layer 40, have two distinct interfaces. There is a first interface 50 between the top electrode 40 and the resistive material layer 30, and a second interface 55 between the resistive material layer 30 and the bottom electrode 20. In some cases, the conduction between the bottom electrode 20, the resistive material layer 30 and top electrode 40 is achieved through tunneling of electrons through a potential barrier at each of these interfaces. The ability to move electrons across these first and second interfaces 50, 55 may contribute to the performance of the device 10. For example, poor electrical conduction between the top electrode 40 and the resistive material layer 30 (or the resistive material layer 30 and the bottom electrode 20) may hinder the ability to form the conductive path between the bottom electrode 20 and top electrode 40 through the resistive material layer 30. This, in turn may force higher voltages to be used to create or remove these paths. In some embodiments, this may reduce the reliability of the device 10. In other embodiments, the resistance of the device 10 in the “on” and “off” state may vary, often to an unacceptable degree.

Therefore, it would be beneficial if there were a method to improve the conductivity between the electrodes of a resistive RAM and the resistive material layer between these electrodes.

### SUMMARY

An improved method of fabricating a resistive memory device is disclosed. A resistive memory includes a bottom electrode, a top electrode and a resistive material layer interposed therebetween. Interfaces are formed between the resistive material layer and the respective top and bottom electrodes. Ions are implanted in the device to change the characteristics of one or both of these interfaces, thereby improving the performance of the memory device. These ions may be implanted after the three layers are fabricated, during the fabrication of these layers, or at both times.

### BRIEF DESCRIPTION OF THE DRAWINGS

For a better understanding of the present disclosure, reference is made to the accompanying drawings, which are incorporated herein by reference and in which:

FIG. 1 is an example of a resistive memory device;

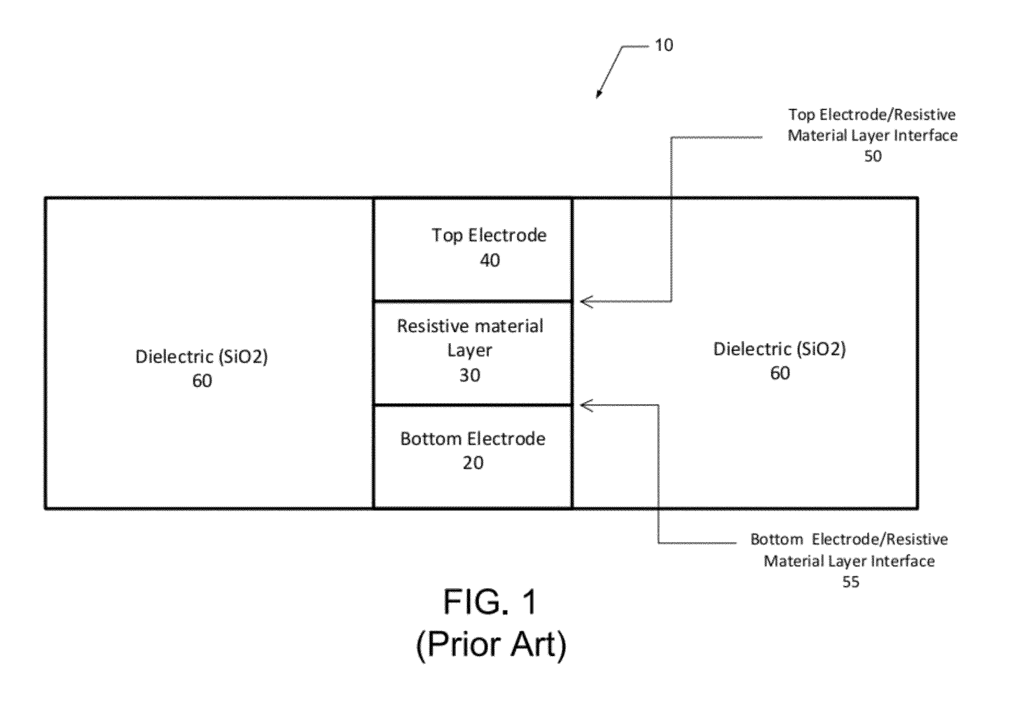

FIG. 2 is a first embodiment implanting through the top electrode;

FIG. 3 is a graph showing aluminum distribution using the embodiment of FIG. 2 at a first implant energy;

FIG. 4 is a graph showing aluminum distribution using the embodiment of FIG. 2 at a second implant energy;

FIG. 5 is a representation of the result of the implant of FIG. 2;

FIG. 6 is a second embodiment implanting without the top electrode;

FIG. 7 is a representation of the result of the implant of FIG. 6; and

FIG. 8 is a representation of the result of a lower energy implant according to FIG. 6.

### DETAILED DESCRIPTION

As new resistive memory technologies are developed, issues of reliability, repeatability and performance may hinder their advancement. In some cases, some of these issues are caused by the electrical conduction between the electrodes, both top and bottom, and the resistive material layer between them. Improvements in this interface may improve these characteristics of resistive memories, such as switching time and yield, thereby enabling their productization.

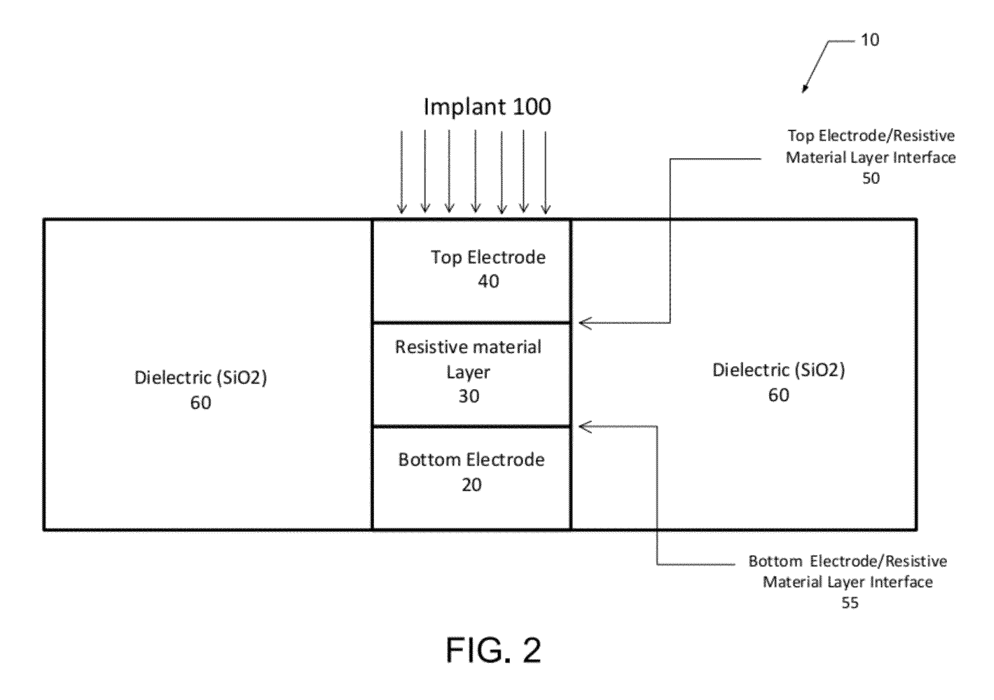

In a first embodiment, shown in FIG. 2, resistive memory device 10 is fabricated, such as in accordance with the methods of the prior art, including CVD, physical vapor deposition (PVD), and atomic layer deposition (ALD). After the top electrode 40 has been applied or formed, an implant 100 is performed. In a first embodiment, the implant 100 is comprised of an inert species, such as argon, neon or krypton. In other embodiments, the species is a dopant, such as boron, phosphorus, or arsenic. In other embodiments, the species is a metal, such as aluminum, silicon, titanium, hafnium, nickel, tungsten, copper, or silver. In other embodiments, the species may be oxygen, hydrogen, carbon, fluorine, chlorine or a molecule such as CH₄.

The depth of the implant 100 is controlled by using an appropriate energy level, such that the ions penetrate the top electrode 40, which may be metal, and enter the targeted region in the resistive material layer 30.

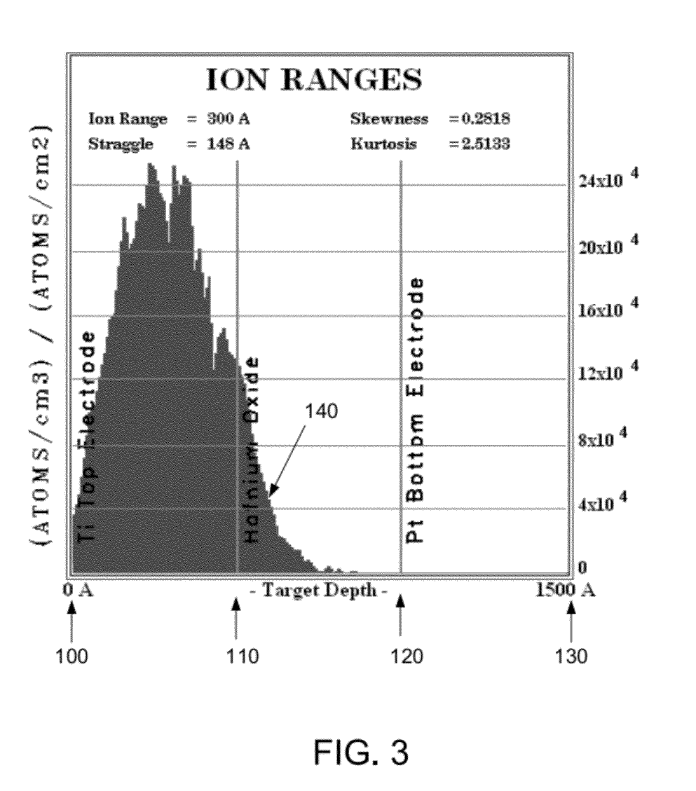

For example, in one embodiment, it may be desired to implant a metal into the interface 50 and upper portion of the resistive material layer 30. FIG. 3 shows a specific example of this embodiment. In this example, the top electrode 40 is titanium, the resistive material layer 30 is hafnium oxide and the bottom electrode 20 is platinum. Each of these layers is 500 angstroms in thickness. Using aluminum as the implant species and an implant energy of 25 keV, a depth profile can be obtained. Line 110 represents interface 50, while line 120 represents interface 55. The space between line 100 and line 110 represents the thickness of the top electrode 40; the space between line 110 and line 120 represents the thickness of the resistive material layer 30; and the space between line 120 and line 130 represents the thickness of the bottom electrode 20. FIG. 3 shows that the target depth is about 300 angstroms, or about 50% of the way through the top electrode 40. The tail of the ion distribution crosses into the resistive material layer 30, as shown in region 140. In other words, at least a portion of the implanted ions are implanted at the interface 50. These ions perform several important functions. First, they produce some doping in a portion of the resistive material layer 30, thereby enabling the conductive path to more easily form. Second, the implanted ions tend to “rough up” the interface 50 between the top electrode 40 and the resistive material layer 30. A less smooth interface 50 is more conducive to better contacts between the layers. A third benefit of such an implant is the ion beam mixing that occurs at the interface 50. As the aluminum ions penetrate the top electrode 40, which may be titanium, some of these energetic aluminum ions knock against the titanium atoms. The momentum transferred from the energetic aluminum ions to the titanium atoms may “push” titanium ions out of the top electrode 40 and into the resistive material layer 30. This ion beam mixing creates a grading at the interface 50, such that there is a smoother transition of concentrations between the metal of the electrode 40 and the resistive material of the resistive material layer 30. This gradient may create a better conductive path between the layers, and reduce the voltage necessary to create a nanowire or filament. While specific depths and energy levels are disclosed above, in other embodiments, these parameters can be modified to obtain similar results.

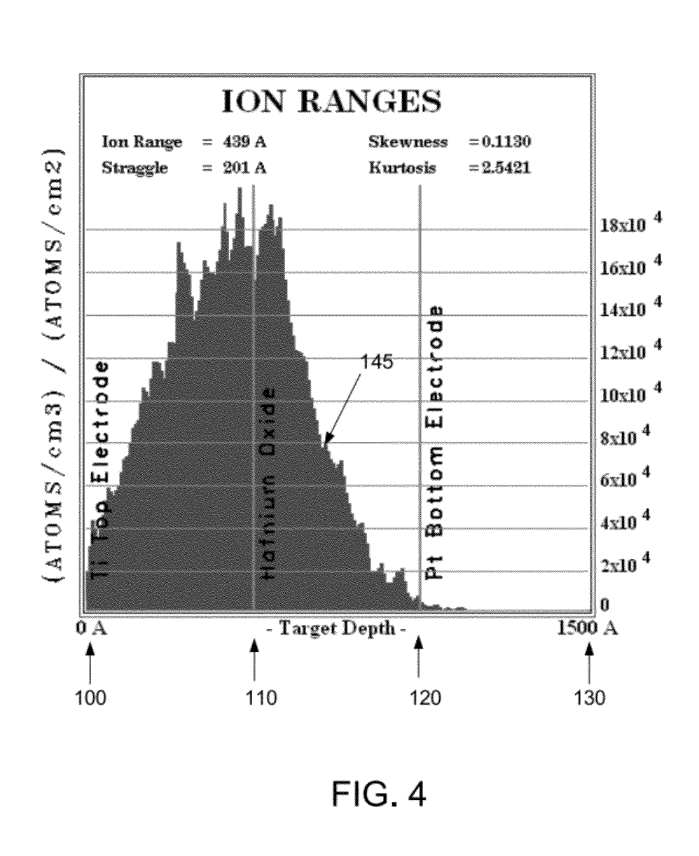

FIG. 4 shows a second example of aluminum implantation into a resistive memory device 10. The device 10 is as described with respect to FIG. 3 and will not be repeated. In this embodiment, the implant energy is increased from 25 keV to 40 keV. As seen in the FIG. 4, this moves the target implant depth to about 500 angstroms, which is the depth of the interface 50. In other words, at this implant energy a grater portion of the implanted ions are implanted at the interface 50. In this embodiment, more aluminum ions pass into the resistive material layer 30, as shown by region 145.

It should be noted that implant 100 does not need to be performed at a single implant energy. For example, to create a more uniform distribution of ions through the resistive material layer 30, an implant having multiple implant energies may be performed.

Therefore, in summary, an ion implant, such as that shown in FIG. 2, can provide several benefits. First, the ion beam mixing may create a gradient between the top electrode 40 and the resistive material layer 30. By properly selecting the ions and the implant energy, the gradient can be controlled. Second, this implant may also serve to roughen the interface 50. The ion implant may also generate defects at the interface 50 between the top electrode 40 and the resistive material layer 30. This implant also serves to dope the interface 50 between the top electrode 40 and the resistive material layer 30, as well as doping at least a portion of the resistive material in the resistive material layer 30.

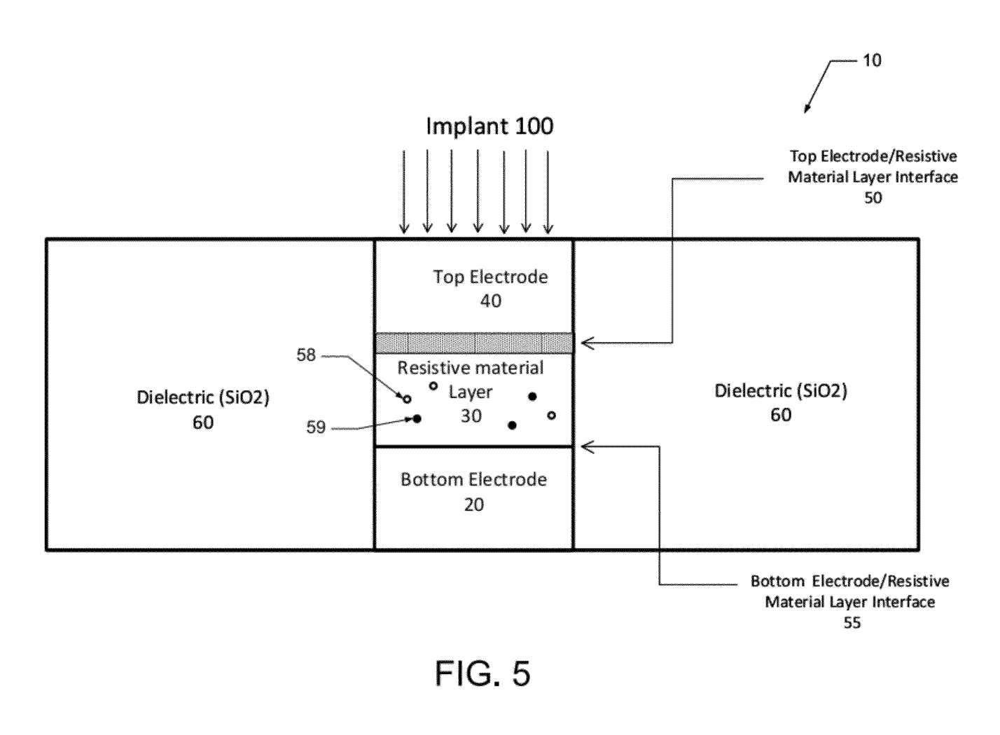

FIG. 5 shows the effects of the implant of FIG. 2. Note that the interface 50 between the top electrode 40 and the resistive material layer 30 is less defined, as illustrated by the shaded region, as there is now mixing of the implanted species, atoms from the top electrode, and resistive material at this interface 50. In addition, defects 58 and dopants 59 are now in the resistive material layer 30 as a result of the ion implant 100.

While the above description described modifications made to the interface 50 between the top electrode 40 and the resistive material layer 30, this embodiment is not limited to this application. For example, by increasing the implant energy, such as to 100 keV, the interface 55 between the resistive material layer 30 and the bottom electrode 20 can be affected by the ion implant 100. In other words, at least a portion of the implanted ions are implanted at the interface 55. In this embodiment, the interface 55 will also become a gradient, with ions from the resistive material layer 30 moving into the bottom electrode 20. In addition, defects 58 and dopants 59 may be implanted in the resistive material layer 30 as a result of this ion implant.

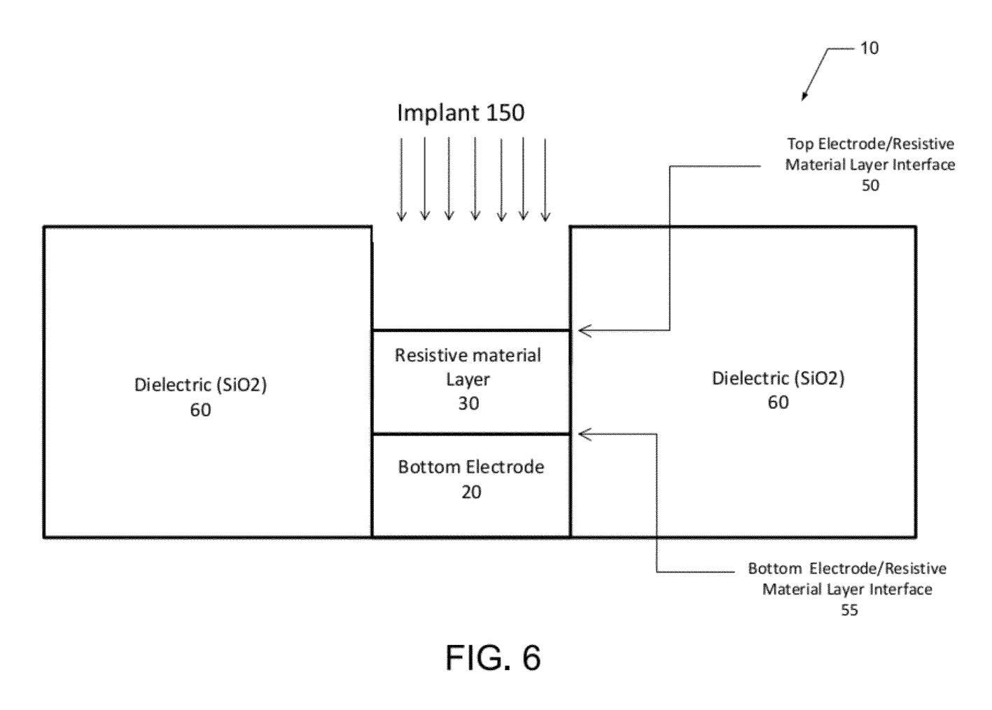

FIG. 6 shows another embodiment of the present method. In this embodiment, the ion implant 150 is performed prior to the application or formation of the top electrode 40. Thus, the implant energy needed to reach interface 55 is much less than that needed using the implant shown in FIG. 2. For example, implant energies of 25 to 50 keV can be used as compared to the aforementioned 100 keV. The species used for implant 150 may be any of those described above. In addition, the benefits of this implant 150 are the same as those described above.

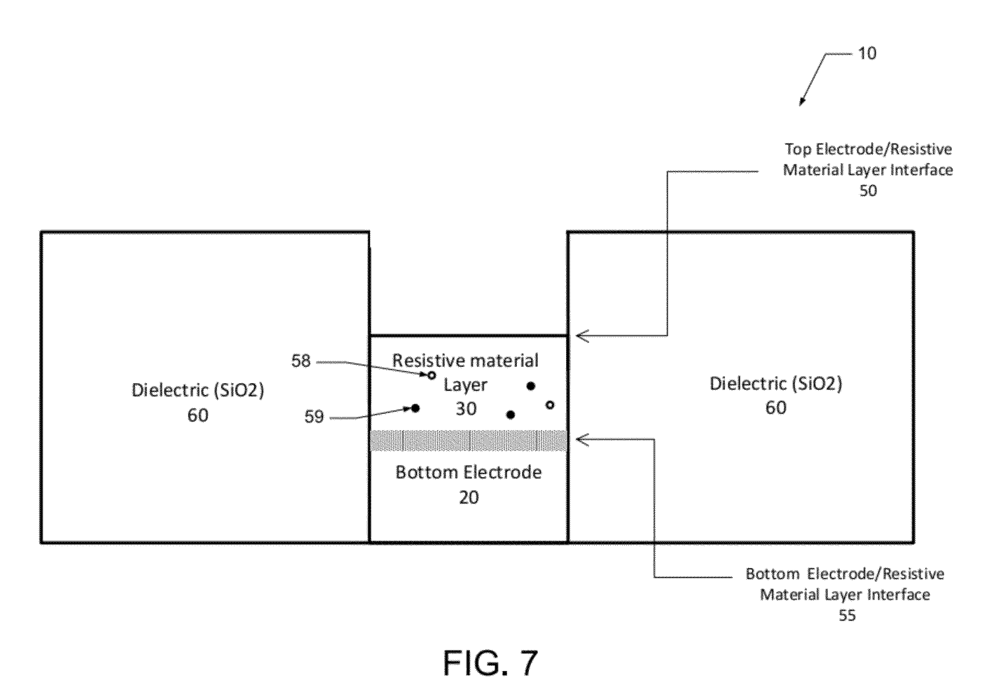

FIG. 7 shows pictorially the effects of implant 150. As can be seen, the interface 55 is now graded, and defects 58 and dopants 59 exist in the resistive material layer 30.

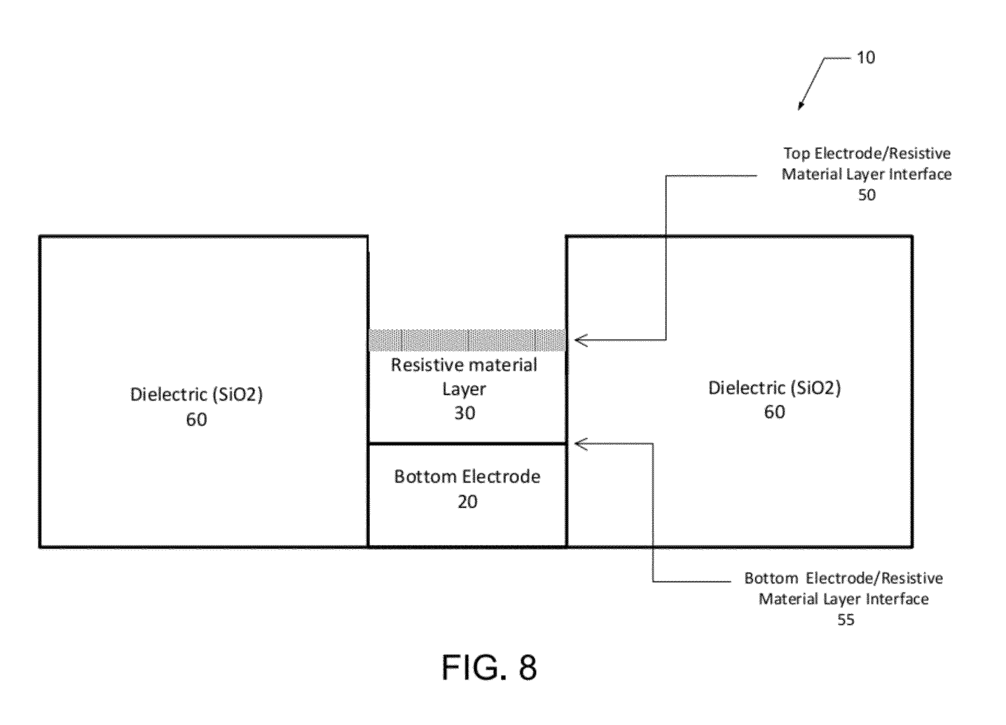

In another embodiment, implant 150 is very low energy, such as less than 5 keV. In this embodiment, the implant serves to perform a very shallow implant, affecting only the top layer of the resistive material layer 30. This shallow implant may result in better conduction when the top electrode 40 is applied to the resistive material layer 30. FIG. 8 shows the result of this shallow implant.

In another embodiment, a combination of these processes is performed. For example, after the deposition of the resistive material layer 30, but prior to the application or formation of the top electrode 40, an implant 150 may be performed, as shown in FIG. 6, resulting in the graded interface 55 shown in FIG. 7. Optionally, a low energy implant may also be performed, resulting in the implanted interface 50, as shown in FIG. 8. After this implant 150, the top electrode 40 is applied to the resistive material layer 30. Implant 100 may then be performed, resulting in a gradient at the interface 50 as shown in FIG. 5.

The implant energies and species used during each of these implants may be different. These implants may be performed using any type of ion implantation equipment, including but not limited to beam-line ion implanters, plasma deposition systems (PLAD), implanters that modify a plasma sheath, and other focused beam systems.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of fabricating a memory device, comprising:
forming a bottom electrode;
forming a resistive material layer on said bottom electrode with a first interface therebetween;
forming a top electrode on said resistive material layer with a second interface therebetween; and
implanting ions into said top electrode at an energy sufficient such that said ions are implanted at said first interface or at said second interface.

2. The method of claim 1, wherein said bottom electrode and said top electrode are each formed of a species selected from the group consisting of nickel, hafnium, titanium, titanium nitride, tantalum, tantalum nitride, tungsten, copper, platinum, and silver.

3. The method of claim 1, wherein said memory device comprises a resistive memory device and said resistive material layer is formed of a transition metal oxide.

4. The method of claim 1, wherein said memory device comprises a conducting bridge RAM and said resistive material layer is formed of a species selected from the group consisting of germanium sulfide (GeSₓ) and germanium selenide (GeSeₓ).

5. The method of claim 1, wherein said memory device comprises a phase change RAM and said resistive material layer is formed of a chalcogenide glass.

6. The method of claim 1, wherein said ions are implanted after said bottom electrode, said resistive material layer and said top electrode are formed.

7. The method of claim 6, wherein said ions are implanted at an energy sufficient so as to be implanted at said second interface.

8. The method of claim 6, wherein said ions are implanted at an energy sufficient so as to be implanted at said first interface.

9. The method of claim 1, wherein said implanted ions comprise a species selected from the group consisting of an inert element, a dopant, a metal, oxygen, hydrogen, carbon, fluorine, chlorine and CH₄.

10. A method of fabricating a memory device, comprising:
forming a bottom electrode;
forming a resistive material layer on said bottom electrode with a first interface therebetween;
implanting ions into said resistive material layer at an energy sufficient such that said ions are implanted at said first interface or at a top surface of said resistive material layer;
forming a top electrode on said resistive material layer with a second interface therebetween, after said implanting step is performed.

11. The method of claim 10, wherein said ions are implanted at an energy sufficient so as to be implanted at said first interface.

12. The method of claim 10, wherein said ions are implanted at an energy sufficient so as to be implanted at said top surface of said resistive material layer.

13. The method of claim 10, further comprising implanting ions into said device after said top electrode is formed.

14. The method of claim 13, wherein said ions are implanted at an energy sufficient so as to implanted at said second interface.

15. The method of claim 10, wherein said bottom electrode and said top electrode are each formed of a species selected from the group consisting of nickel, hafnium, titanium, titanium nitride, tantalum, tantalum nitride, tungsten, copper, platinum, and silver.

16. The method of claim 10, wherein said memory device comprises a resistive memory device and said resistive material layer is formed of a transition metal oxide.

17. The method of claim 10, wherein said memory device comprises a conducting bridge RAM and said resistive material layer is formed of a species selected from the group consisting of germanium sulfide (GeSₓ) and germanium selenide (GeSeₓ).

18. The method of claim 10, wherein said memory device comprises a phase change RAM and said resistive material layer is formed of a chalcogenide glass.

19. The method of claim 10, wherein said implanted ions comprise a species selected from the group consisting of an inert element, a dopant, a metal, oxygen, hydrogen, carbon, fluorine, chlorine and CH₄.

20. A method of fabricating a memory device, comprising:
forming a bottom electrode;
forming a resistive material layer on said bottom electrode with a first interface therebetween;
implanting ions into said resistive material layer such that said ions are implanted at an energy sufficient so as to be implanted at said first interface;
implanting ions into said resistive material layer at an energy sufficient so as to be implanted at a top surface of said resistive material layer;
forming a top electrode on said resistive material layer after said implanting steps are performed.
